(19) United States
(12) Patent Application Publication
(10) Pub. No.: US 2025/0210088 A1
(43) Pub. Date: Jun. 26, 2025

(54) POWER MANAGEMENT CIRCUIT AND STORAGE DEVICE

(71) Applicant: SK hynix Inc., Icheon-si (KR)

(72) Inventor: Min Soon HWANG, Icheon-si (KR)

(21) Appl. No.: 18/960,804

(22) Filed: Nov. 26, 2024

(30) Foreign Application Priority Data
Dec. 22, 2023 (KR) 10-2023-0190517

(51) Int. Cl. G11C 11/4074; G11C 11/4076; G11C 11/4099

(52) U.S. Cl. CPC G11C 11/4074; G11C 11/4076; G11C 11/4099

(57) ABSTRACT

A power management circuit that supplies a voltage for driving a memory outputs, to the memory, a voltage that is adjusted on the basis of a driving reference voltage inputted from the outside and operation timing information and operation status information of the memory received from a controller. Therefore, it is possible to improve the performance of the memory that operates using a voltage supplied from the power management circuit while maintaining voltage supply efficiency.

### CROSS-REFERENCE TO RELATED APPLICATION

The present application claims priority under 35 U.S.C. § 119(a) to Korean Patent Application No. 10-2023-0190517 filed in the Korean Intellectual Property Office on Dec. 22, 2023, which is incorporated herein by reference in its entirety.

### BACKGROUND

### 1. Technical Field

Embodiments of the present disclosure relate to a power management circuit and a storage device.

### 2. Related Art

A storage device may include a memory including a plurality of memory cells that store data. The storage device may include a controller that controls the operation of the memory. For example, the controller may control an operation of writing data to the memory or reading or erasing data written to the memory.

The storage device may include a power management circuit which supplies voltages for driving the memory and the controller. For example, the power management circuit may generate a driving voltage on the basis of a reference voltage input from the outside and supplying the driving voltage to the memory or the controller.

In this case, voltage efficiency may be high by using a reference voltage inputted from the outside, but a problem may arise in that the operational performance of the memory or the like may degrade because of the difficulties in voltage adjustment depending on the operation status of the memory or the controller.

### SUMMARY

Various embodiments of the present disclosure are directed to providing measures capable of performing adaptive voltage adjustment based on the operation status of a memory or a controller while maintaining voltage efficiency by a power management circuit included in a storage device.

In an embodiment, a storage device may include: at least one memory; a controller configured to control an operation of the at least one memory; and a power management circuit configured to receive a driving reference voltage from an outside, receive operation timing information according to a command transmitted from the controller to the at least one memory, and output, to the at least one memory, a first operation correction voltage of a first range or a second operation correction voltage of a second range that is adjusted from the driving reference voltage on the basis of the operation timing information.

In an embodiment, a power management circuit may include: a voltage adjuster configured to output a voltage adjustment control signal based on at least one of operation timing information or operation status information received from a controller; and a voltage output configured to receive a driving reference voltage from an outside, and output at least one operation correction voltage that is obtained as the driving reference voltage is adjusted according to the voltage adjustment control signal.

In an embodiment, a power management circuit may include: a first output configured to output a first operation reference voltage that is different from a driving reference voltage received from an outside; a second output configured to output a second operation reference voltage that corresponds to the driving reference voltage; and a switching unit including a plurality of switches each of which electrically connects each of a plurality of output terminals and the first output or the second output, wherein at least two switches among the plurality of switches are electrically connected simultaneously to the first output or the second output.

In an embodiment, a storage device may include: at least one memory; a controller configured to control an operation of the at least one memory; and a power management circuit configured to receive a driving reference voltage from an outside, to receive operation timing information or operation status information from the controller, and to output, to the at least one memory, a driving voltage that is adjusted from the driving reference voltage based on the operation timing information or the operation status information.

According to the embodiments of the present disclosure, it is possible to improve the operational performance of a memory or the like supplied with a driving voltage based on a reference voltage inputted from the outside of a storage device while maintaining the supply efficiency of the driving voltage.

### BRIEF DESCRIPTION OF THE DRAWINGS

FIG. 1 is a diagram illustrating an example of a schematic configuration of a storage device according to embodiments of the present disclosure.

FIG. 2 is a diagram illustrating an example of a schematic configuration of a memory included in a storage device according to embodiments of the present disclosure.

FIG. 3 is a diagram illustrating an example of a configuration for controlling a driving voltage in a storage device according to embodiments of the present disclosure.

FIG. 4 is a diagram illustrating an example of a structure of a power management circuit included in a storage device according to embodiments of the present disclosure.

FIG. 5 is a diagram illustrating an example of a configuration for controlling a driving voltage in a storage device according to embodiments of the present disclosure.

FIGS. 6 and 7 are diagrams illustrating examples in which driving voltages are adjusted by a power management circuit included in a storage device according to embodiments of the present disclosure.

FIG. 8 is a diagram illustrating an example of a configuration for controlling a driving voltage in a storage device according to embodiments of the present disclosure.

FIGS. 9 and 10 are diagrams illustrating an example of a scheme in which driving voltage control is performed in a storage device illustrated in FIG. 8.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings. Further, in the following description of examples or embodiments of the present disclosure, detailed descriptions of well-known functions and components incorporated herein will be omitted when it is determined that the description may make the subject matter in some embodiments of the present disclosure rather more unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, or manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance range or error margin that may be caused by various factors (e.g., process factors, internal or external impact, noise, etc.) even when a relevant description is not specified. Further, the term “may” fully encompass all the meanings of the term “can.”

Hereinafter, various embodiments of the present disclosure will be described in detail with reference to accompanying drawings.

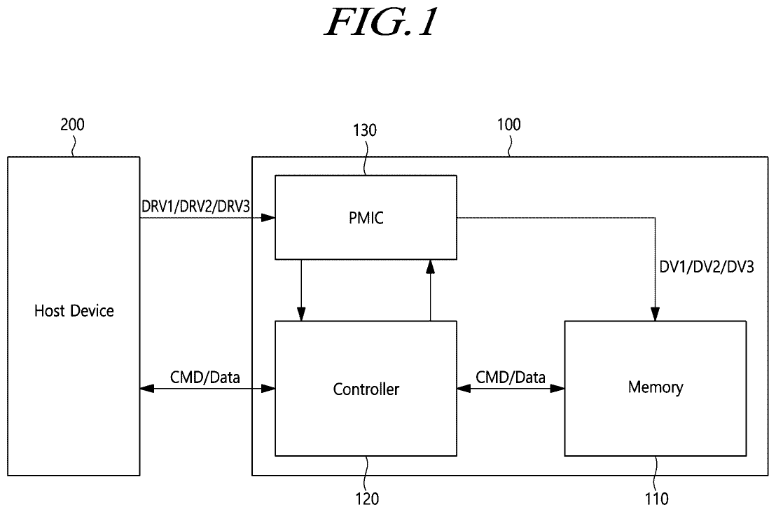

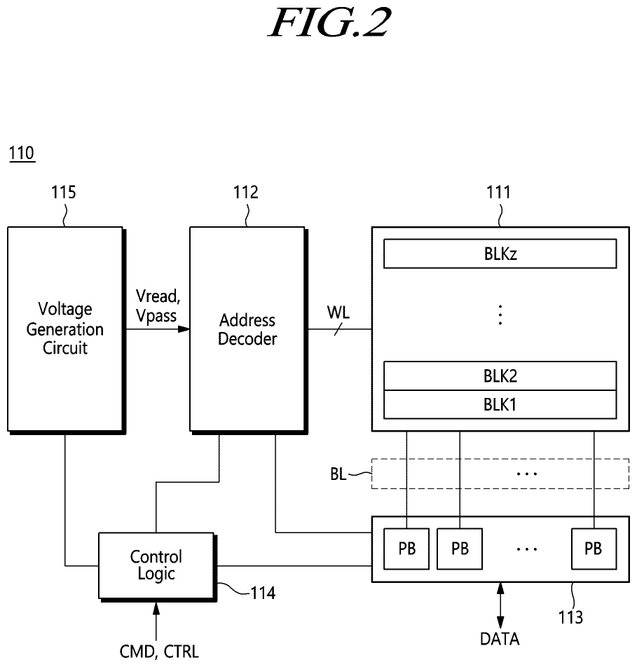

FIG. 1 is a diagram illustrating an example of a schematic configuration of a storage device according to embodiments of the present disclosure. FIG. 2 is a diagram illustrating an example of a schematic configuration of a memory included in a storage device according to embodiments of the present disclosure.

Referring to FIG. 1, a storage device 100 may include at least one memory 110. The storage device 100 may include a controller 120, which controls the at least one memory 110. The storage device 100 may include a power management circuit 130, which supplies a voltage for driving the memory 110 or the controller 120.

The memory 110 may be implemented in various types such as, for example, NAND flash memory, 3D NAND flash memory, NOR flash memory, resistive RAM, phase change memory, magnetoresistive memory, ferroelectric memory or spin transfer torque memory. The memory 110 may be implemented into a three-dimensional array structure. The embodiments of the present disclosure may be applied to not only flash memory in which a charge storage layer is configured with a floating gate, but also charge trap flash in which a charge storage layer is configured with an insulating layer.

The memory 110 may include a plurality of memory blocks (or storage blocks). The memory 110 may include various circuits for driving and controlling the plurality of memory blocks.

For example, referring to FIG. 2, the memory 110 according to the embodiments of the present disclosure may include a memory cell array 111, an address decoder 112, a read and write circuit 113, a control logic 114 and a voltage generation circuit 115.

The memory cell array 111 may include a plurality of storage blocks BLK1 to BLKz (where z is a natural number of 2 or more).

In the plurality of storage blocks BLK, a plurality of word lines WL and a plurality of bit lines BL may be disposed, and a plurality of memory cells may be arranged.

The plurality of storage blocks BLK may be connected to the address decoder 112 through the plurality of word lines WL. The plurality of storage blocks BLK may be connected to the read and write circuit 113 through the plurality of bit lines BL.

Each of the plurality of storage blocks BLK may include a plurality of memory cells. The plurality of memory cells are nonvolatile memory cells, and may be configured with nonvolatile memory cells that have a vertical channel structure.

In some embodiments, the memory cell array 111 may be configured as a memory cell array with a two-dimensional structure, and in other embodiments, may be configured as a memory cell array with a three-dimensional structure.

Each of the plurality of memory cells included in the memory cell array 111 may store at least 1 bit of data. For example, each of the plurality of memory cells included in the memory cell array 111 may be a single-level cell (SLC), which stores 1 bit of data. In another example, each of the plurality of memory cells included in the memory cell array 111 may be a multi-level cell (MLC) that stores 2 bits of data, a triple-level cell (TLC) that stores 3 bits of data, a quad-level cell (QLC) that stores 4 bits of data or a memory cell that stores at least 5 bits of data.

The number of bits of data stored in each of the plurality of memory cells may be dynamically determined. For example, a single-level cell that stores 1 bit of data may be changed to a triple-level cell that stores 3 bits of data.

The address decoder 112, the read and write circuit 113, the control logic 114 and the voltage generation circuit 115 may operate as peripheral circuits that drive the memory cell array 111.

The address decoder 112 may be connected to the memory cell array 111 through the plurality of word lines WL. The address decoder 112 may be configured to operate in response to control of the control logic 114.

The address decoder 112 may receive an address through an input/output buffer in the memory 110. The address decoder 112 may be configured to decode a block address in the received address. The address decoder 112 may select at least one storage block BLK according to the decoded block address.

The address decoder 112 may receive a read voltage Vread and a pass voltage Vpass from the voltage generation circuit 115.

In an operation of applying the read voltage Vread during a read operation, the address decoder 112 may apply the read voltage Vread to a selected word line WL in a selected storage block BLK, and may apply the pass voltage Vpass to remaining unselected word lines WL.

In a program verify operation, the address decoder 112 may apply a verify voltage generated in the voltage generation circuit 115 to a selected word line WL in a selected storage block BLK, and may apply the pass voltage Vpass to remaining unselected word lines WL.

The address decoder 112 may be configured to decode a column address in the received address. The address decoder 112 may transmit the decoded column address to the read and write circuit 113.

A read operation and a program operation of the memory 110 may be performed in the unit of a page. An address received when each of the read operation and the program operation is requested may include at least one of a block address, a row address and a column address.

The address decoder 112 may select one storage block BLK and one word line WL according to the block address and the row address. The column address may be decoded by the address decoder 112, and the decoded column address may be provided to the read and write circuit 113.

The address decoder 112 may include at least one of a block decoder, a row decoder, a column decoder and an address buffer.

The read and write circuit 113 may include a plurality of page buffers PB. The read and write circuit 113 may operate as a read circuit in a read operation of the memory cell array 111, and may operate as a write circuit in a write operation of the memory cell array 111.

The read and write circuit 113 may also be referred to as a page buffer circuit or a data register circuit that includes the plurality of page buffers PB. The read and write circuit 113 may include a data buffer that takes charge of a data processing function, and may additionally include a cache buffer that takes charge of a caching function.

The plurality of page buffers PB may be connected to the memory cell array 111 through the plurality of bit lines BL. In order to sense threshold voltages (Vth) of memory cells in a read operation and a program verify operation, the plurality of page buffers PB may continuously supply sensing current to bit lines BL connected to the memory cells, and may latch sensing data by sensing, through sensing nodes, changing amounts of current flowing according to programmed states of the corresponding memory cells.

The read and write circuit 113 may operate in response to page buffer control signals output from the control logic 114.

In a read operation, the read and write circuit 113 may temporarily store read data by sensing data of memory cells, and then, may output data DATA to the input/output buffer of the memory 110. As an exemplary embodiment, the read and write circuit 113 may include a column select circuit and so on in addition to the page buffers PB or page registers.

The control logic 114 may be connected to the address decoder 112, the read and write circuit 113 and the voltage generation circuit 115. The control logic 114 may receive a command CMD and a control signal CTRL through the input/output buffer of the memory 110.

The control logic 114 may be configured to control overall operations of the memory 110 in response to the control signal CTRL. The control logic 114 may output a control signal for adjusting the precharge potential level of the sensing nodes of the plurality of page buffers PB.

The control logic 114 may control the read and write circuit 113 to perform a read operation of the memory cell array 111. The voltage generation circuit 115 may generate the read voltage Vread and the pass voltage Vpass used in the read operation, in response to a voltage generation circuit control signal output from the control logic 114.

Each of the storage blocks BLK of the memory 110 described above may be composed of a plurality of pages corresponding to a plurality of word lines WL and a plurality of strings corresponding to a plurality of bit lines BL.

In a storage block BLK, a plurality of word lines WL and a plurality of bit lines BL may be disposed to intersect each other. A memory cell connected to one of the plurality of word lines WL and one of the plurality of bit lines BL may be defined. A transistor may be disposed in each memory cell.

A transistor disposed in a memory cell may include a drain, a source and a gate. The drain (or source) of the transistor may be connected to a corresponding bit line BL directly or via another transistor. The source (or drain) of the transistor may be connected to a source line (which may be the ground) directly or via another transistor. The gate of the transistor may include a floating gate that is surrounded by a dielectric and a control gate to which a gate voltage is applied from a word line WL.

In each storage block BLK, a first select line (also referred to as a source select line or a drain select line) may be additionally disposed outside a first outermost word line WL more adjacent to the read and write circuit 113 between two outermost word lines WL, and a second select line (also referred to as a drain select line or a source select line) may be additionally disposed outside a second outermost word line WL between the two outermost word lines WL.

In some embodiments, at least one dummy word line may be additionally disposed between the first outermost word line and the first select line. At least one dummy word line may also be additionally disposed between the second outermost word line and the second select line.

A read operation and a program operation (write operation) of the storage block BLK described above may be performed in the unit of a page, and an erase operation may be performed in the unit of a memory block.

A program operation, an erase operation and a read operation of the memory 110 may be performed in response to the control of the controller 120.

The controller 120 may control program, erase, read and background operations for the memory 110. The background operation may include, for example, at least one among garbage collection, wear leveling, read reclaim and bad block management operations.

The controller 120 may control the operation of the memory 110 according to a request from a device located outside the storage 1o device 100. In addition, the controller 120 may control the operation of the memory 110 regardless of a request from the outside.

For example, the controller 120 may control the operation of the memory 110 according to a request from a host device 200. The storage device 100 and the host device 200 may be collectively referred to as a computing system.

For example, the host device 200 may be a computer, an ultra mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a telematics network, an REID (radio frequency identification) device, a mobility device (e.g., a vehicle, a robot or a drone) capable of traveling under human control or autonomous driving, or the like. Alternatively, the host device 200 may be a virtual/augmented reality device that provides a 2D or 3D virtual reality image or augmented reality image. In addition, the host device 200 may be any one of various electronic devices each of which requires the storage device 100 capable of storing data.

The host device 200 may include at least one operating system. The operating system may manage and control overall functions and operations of the host device 200, and may control an interoperation between the host device 200 and the storage device 100. The operating system may be classified into a general operating system and a mobile operating system depending on the mobility of the host device 200.

The controller 120 and the host device 200 may be devices that are separated from each other, or the controller 120 and the host device 200 may be implemented by being integrated into one device. Hereunder, for the sake of convenience in explanation, it will be described as an example that the controller 120 and the host device 200 are devices that are separated from each other.

The controller 120 may include a host interface that provides an interface for communication with the host device 200. The controller 120 may include a memory interface that provides an interface for communication with the memory 110.

The controller 120 may include a control circuit that controls overall operations of the controller 120. The control circuit may include, for example, a processor and a working memory that is used for the operation of the processor, and optionally include an error detection and correction circuit.

The processor may communicate with the host device 200 through the host interface and may communicate with the memory 110 through the memory interface.

The processor may perform a function of interpreting a command input from the host device 200 and transfer the command to the memory 110. For example, the processor may include a flash translation layer or may correspond to a flash translation layer. The processor may translate a logical block address provided by the host device 200 into a physical block address. The processor may receive a logical block address and translate the logical block address into a physical block address using a mapping table.

For example, the processor may execute firmware to control the operation of the controller 120. An operation of the storage device 100 described in embodiments of the present disclosure may be implemented in such a way that the processor executes firmware in which the corresponding operation is defined.

In order to control the overall operations of the controller 120, the processor may perform a logical operation that is defined in the firmware loaded in the working memory. According to a result of performing the logical operation defined in the firmware, the processor may control the controller 120 to generate a command or a signal. When a part of firmware in which a logical operation to be performed is defined is not loaded in the working memory, the processor may generate an event (e.g., an interrupt) for loading the corresponding part of the firmware in the working memory.

The working memory may store firmware, program codes, commands or data necessary to drive the controller 120.

The working memory may be located inside or outside the controller 120, or the working memories may be located inside and outside the controller 120.

The working memory as, for example, a volatile memory, may include at least one among SRAM (static RAM), DRAM (dynamic RAM) and SDRAM (synchronous DRAM).

The power management circuit 130 may output a voltage to be used for the operation of the memory 110 or the controller 120.

For example, the power management circuit 130 may receive at least one driving reference voltage DRV from the outside. FIG. 1 illustrates, as an example, the power management circuit 130 receiving a first driving reference voltage DRV1, a second driving reference voltage DRV2 and a third driving reference voltage DRV3 from the host device 200, but embodiments of the present disclosure are not limited thereto.

The first driving reference voltage DRV1 to the third driving reference voltage DRV3 may be voltages which have different levels.

The power management circuit 130 may output at least one driving voltage DV for driving the memory 110 or the controller 120, using the driving reference voltage DRV received from the outside.

For example, the power management circuit 130 may output a first driving voltage DV1, a second driving voltage DV2 and a third driving voltage DV3 to the memory 110. The first driving voltage DV1, the second driving voltage DV2 and the third driving voltage DV3 may be voltages that have different levels.

Various driving voltages DV that are supplied to the memory 110 may be used to drive a word line WL or a bit line BL included in the memory 110, and may be used for a data signal transmitted and received between the memory 110 and the controller 120.

Since the power management circuit 130 supplies the driving voltage DV to the memory 110 or the like using the driving reference voltage DRV received from the outside, the supply performance or efficiency of the driving voltage DV may be high.

In embodiments of the present disclosure, the power management circuit 130, which operates by receiving the driving reference voltage DRV from the outside, adjusts and outputs the driving voltage DV on the basis of information received from the controller 120, and thereby, it is possible to provide measures capable of improving the operational efficiency of the memory 110, or the like, which operates by being supplied with the driving voltage DV by the power management circuit 130.

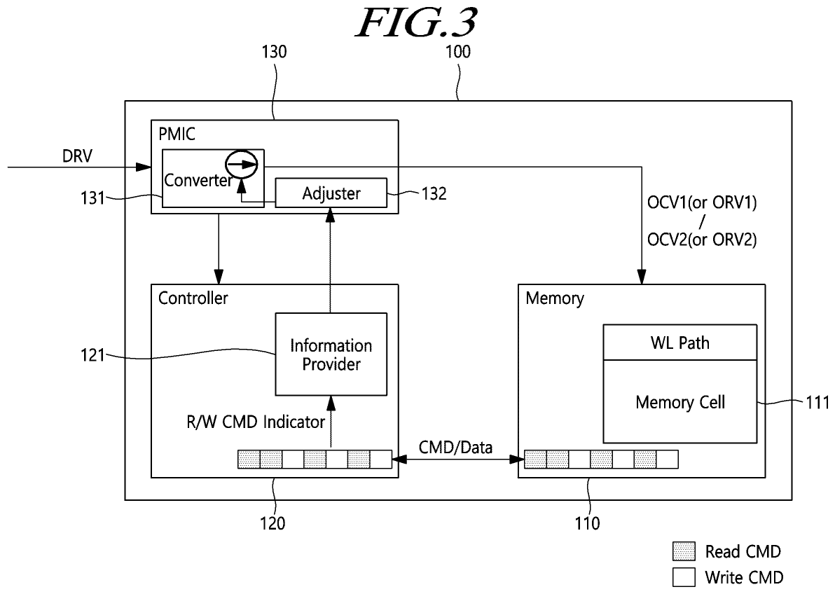

FIG. 3 is a diagram illustrating an example of a configuration for controlling a driving voltage DV in a storage device according to embodiments of the present disclosure.

Referring to FIG. 3, a storage device 100 may include a memory 110, a controller 120 and a power management circuit PMIC 130.

FIG. 3 illustrates, as an example, a storage device 100 including one memory 110, but at least two memories 110 may be included in the storage device 100. The operations of at least two memories 110 may be controlled by the controller 120, and a driving voltage DV may be supplied to the at least two memories 110 by the power management circuit 130.

The memory 110 may include a plurality of memory cells, and may include a plurality of word lines WL that are electrically connected to the memory cells.

The controller 120 may include an information provider 121, which provides information associated with the operation of the memory 110 to the power management circuit 130.

For example, the information provider 121 may transmit, to the power management circuit 130, operation timing information that indicates the operation timing of the memory 110. The operation timing information may include information on timing at which the memory 110 performs a read operation or a write operation.

The information provider 121 may obtain information on the operation timing of the memory 110 through, for example, a command and data transmitted to the memory 110 by the controller 120.

The information provider 121 may, for example, periodically transmit operation timing information to the power management circuit 130. Alternatively, the information provider 121 may transmit operation timing information to the power management circuit 130 when a command or the like to be transmitted to the memory 110 is generated by the controller 120.

Before the memory 110 operates according to a command transmitted by the controller 120, the information provider 121 may obtain operation timing information indicating the operation timing of the memory 110 and provide the operation timing information to the power management circuit 130. A time point and a cycle at or with which the information provider 121 transmits operation timing information to the power management circuit 130 are not limited to the examples described above.

The power management circuit 130 may receive a driving reference voltage DRV from the outside. The power management circuit 130 may output a driving voltage DV based on the driving reference voltage DRV.

The power management circuit 130 may adjust or control the driving reference voltage DRV on the basis of operation timing information received from the controller 120. The power management circuit 130 may output an operation correction voltage OCV or an operation reference voltage ORV which is obtained as the driving reference voltage DRV is adjusted or controlled.

The operation reference voltage ORV may mean, for example, a voltage that has a level set on the basis of the driving reference voltage DRV. The operation correction voltage OCV may mean, for example, a voltage that has a level adjusted within a predetermined range on the basis of the operation reference voltage ORV.

The power management circuit 130 may output the operation reference voltage ORV on the basis of the driving reference voltage DRV, or may output the operation correction voltage OCV, which is adjusted on the basis of the operation reference voltage ORV.

The power management circuit 130 may include, for example, a voltage output 131 and a voltage adjuster 132.

The voltage output 131 may be, for example, a DC-DC converter.

The voltage adjuster 132 may receive operation timing information from the controller 120. The voltage adjuster 132 may output a voltage adjustment control signal to the voltage output 131 on the basis of the operation timing information.

The voltage output 131 may output the operation correction voltage OCV or the operation reference voltage ORV, which is obtained as the driving reference voltage DRV is adjusted or controlled, according to the voltage adjustment control signal depending on the operation timing information.

For example, the voltage output 131 may output a first operation correction voltage OCV1 of a first range, which is obtained as the driving reference voltage DRV is adjusted depending on the operation timing information. The voltage output 131 may output a second operation correction voltage OCV2 of a second range, which is obtained as the driving reference voltage DRV is adjusted depending on the operation timing information.

The driving reference voltage DRV may be included in a range other than, for example, the first range. The first operation correction voltage OCV1 included in the first range may be a voltage that is adjusted from a first operation reference voltage ORV1 that is different from the driving reference voltage DRV.

The first operation reference voltage ORV1 and the first operation correction voltage OCV1 included in the first range may be a driving voltage DV that is outputted to the memory 110 when the memory 110 performs a read operation. The first range may mean a range of the driving voltage DV, which is outputted to the memory 110 in the read operation of the memory 110.

The driving reference voltage DRV may be included in the second range. The second operation correction voltage OCV2 included in the second range may be a voltage that is adjusted from a second operation reference voltage ORV2. The second operation reference voltage ORV2 may be, for example, a voltage corresponding to the driving reference voltage DRV. The second operation reference voltage ORV2 may be a voltage that has the same level as the level of the driving reference voltage DRV.

The second operation reference voltage ORV2 and the second operation correction voltage OCV2 included in the second range may be a driving voltage DV that is outputted to the memory 110 when the memory 110 performs a write operation. The second range may mean a range of the driving voltage DV that is outputted to the memory 110 in the write operation of the memory 110.

The power management circuit 130 may output different driving voltages DV to the memory 110 depending on operation timing information received from the controller 120.

For example, when the timing at which a read operation of the memory 110 is performed depends on operation timing information received from the controller 120 by the power management circuit 130, the power management circuit 130 may output the first operation correction voltage OCV1 based on the driving reference voltage DRV to the memory 110.

When the power management circuit 130 outputs the operation correction voltage OCV on the basis of only operation timing information, the first operation correction voltage OCV1 may mean the same voltage as the first operation reference voltage ORV1. When a read operation of the memory 110 is performed, the power management circuit 130 may output the first operation reference voltage ORV1 to the memory 110.

The first operation reference voltage ORV1, as a voltage that is different from the driving reference voltage DRV, may be a voltage that has a lower level than the driving reference voltage DRV.

In another example, when the timing at which a write operation of the memory 110 is performed depends on operation timing information received from the controller 120 by the power management circuit 130, the power management circuit 130 may output the second operation correction voltage OCV2 based on the driving reference voltage DRV to the memory 110.

Since the power management circuit 130 outputs the operation correction voltage OCV on the basis of only operation timing information, the second operation correction voltage OCV2 may be the same voltage as the second operation reference voltage ORV2. When a write operation of the memory 110 is performed, the power management circuit 130 may output the second operation reference voltage ORV2 to the memory 110.

The second operation reference voltage ORV2, as a voltage that corresponds to the driving reference voltage DRV, may be a voltage which has the same level as the driving reference voltage DRV.

Since the power management circuit 130 outputs the first operation reference voltage ORV1 or the second operation reference voltage ORV2 to the memory 110 on the basis of operation timing information received from the controller 120, a different driving voltage DV may be supplied according to a read operation or a write operation of the memory 110.

The first operation reference voltage ORV1 and the second operation reference voltage ORV2 may be used as any one of voltages used for the operation of the memory 110. For example, the first operation reference voltage ORV1 and the second operation reference voltage ORV2 may be used as a voltage applied to a word line WL included in the memory 110. The first operation reference voltage ORV1 and the second operation reference voltage ORV2 may be used as a pass voltage Vpass applied to a word line WL.

Since a driving voltage DV to be outputted to the memory 110 is adjusted on the basis of operation timing information received from the controller 120, which outputs a read command and a write command to the memory 110, the driving voltage DV may be adjusted accurately according to the operation timing of the memory 110.

In addition, since the power management circuit 130 outputs a driving voltage DV that is adjusted on the basis of the driving reference voltage DRV received from the outside, when compared to a case where a voltage is adjusted inside the memory 110, it is possible to supply a driving voltage DV of an appropriate level according to the operation timing of the memory 110 and also improve voltage supply efficiency by the power management circuit 130.

The voltage output 131 included in the power management circuit 130 may output the first operation reference voltage ORV1 for a read operation or the second operation reference voltage ORV2 for a write operation according to operation timing information received from the controller 120.

Alternatively, the voltage output 131 may separately include a configuration that outputs the first operation reference voltage ORV1 and a configuration that outputs the second operation reference voltage ORV2.

The voltage output 131 may include, for example, a plurality of DC-DC converters, and may control a DC-DC converter that outputs the first operation reference voltage ORV1 or a DC-DC converter that outputs the second operation reference voltage ORV2, to use in operations according to operation timing information.

The power management circuit 130 may include a switching structure for transferring the first operation reference voltage ORV1 or the second operation reference voltage ORV2 to the memory 110. This structure may also be applied to a structure in which the power management circuit 130 supplies a driving voltage DV to a plurality of memories 110.

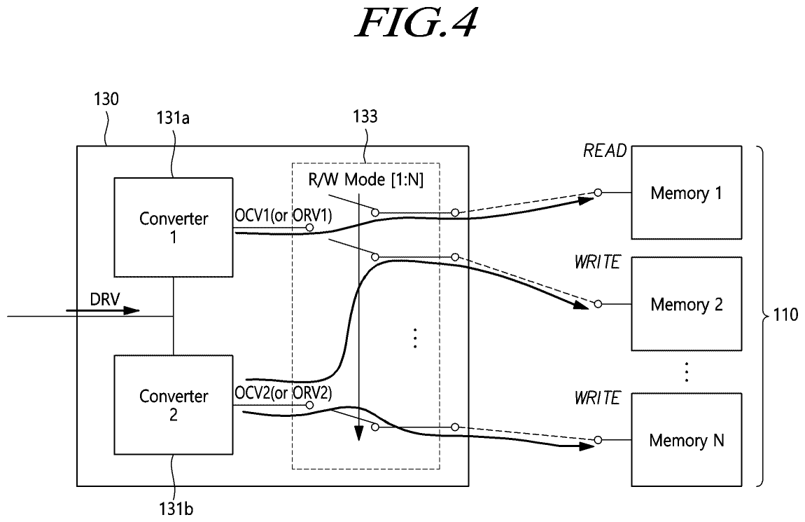

FIG. 4 is a diagram illustrating an example of a structure of a power management circuit included in a storage device 100 according to embodiments of the present disclosure.

FIG. 4 illustrates, as an example, an N number of memories 110 included in a storage device 100 and a driving voltage DV supplied to the N number of memories 110 by a power management circuit 130.

Referring to FIG. 4, the power management circuit 130 may include a first output 131a and a second output 131b. The first output 131a and the second output 131b may be collectively referred to as a voltage output 131 as illustrated in FIG. 3.

The first output 131a and the second output 131b may receive a driving reference voltage DRV from the outside.

The first output 131a may output a first operation correction voltage OCV1 or a first operation reference voltage ORV1 on the basis of the driving reference voltage DRV. The second output 131b may output a second operation correction voltage OCV2 or a second operation reference voltage ORV2 on the basis of the driving reference voltage DRV.

Although not illustrated in FIG. 4, the power management circuit 130 may include a voltage adjuster 132 as in the example illustrated in FIG. 3. The voltage adjuster 132 may receive operation timing information from the controller 120, and may output a voltage adjustment control signal based on the operation timing information.

The power management circuit 130 may include a switching unit 133, which electrically connects the first output 131a and the second output 131b with the plurality of memories 110.

The switching unit 133 may include, for example, a plurality of switches, and may include an N number of output terminals that correspond to the N number of memories 110, respectively. One ends of the plurality of switches included in the switching unit 133 may be electrically connected to the N number of output terminals, and each of the other ends may be electrically connected to one of the first output 131a and the second output 131b.

Each of the plurality of switches included in the switching unit 133 may be electrically connected to one of the first output 131a and the second output 131b on the basis of operation timing information.

For example, the switching unit 133 may operate according to a voltage adjustment control signal based on operation timing information received from the controller 120.

The switching unit 133 may electrically connect a memory, among the N number of memories 110, that performs a read operation according to operation timing information and the first output 131a. The first operation correction voltage OCV1 or the first operation reference voltage ORV1 outputted by the first output 131a may be supplied to the memory that performs the read operation.

The switching unit 133 may electrically connect a memory, among the N number of memories 110, that performs a write operation according to operation timing information and the second output 131b. The second operation correction voltage OCV2 or the second operation reference voltage ORV2 outputted by the second output 131b may be supplied to the memory that performs the write operation.

Since the plurality of switches included in the switching unit 133 are electrically connected to the first output 131a or the second output 131b, at least two switches may be electrically connected simultaneously to the first output 131a and/or the second output 131b depending on operation timing of the plurality of memories 110.

For example, as illustrated in FIG. 4, when a second memory Memory 2 and an Nth memory Memory Namong the plurality of memories 110 perform a write operation, switches connected to the second memory Memory 2 and the Nth memory Memory N, respectively, may be electrically connected simultaneously to the second output 131b.

The supply of a driving voltage DV according to the operation of each of the plurality of memories 110 may be facilitated by the switching unit 133, which controls the first output 131a that outputs the first operation reference voltage ORV1 or the first operation correction voltage CRV1, which is separated from the second output 131b that outputs the second operation reference voltage ORV2 or the second operation correction voltage OCV2 and the connection between the first and second outputs 131a and 131b and the plurality of memories 110.

In addition, since the switching unit 133 operates on the basis of operation timing information received from the controller 120, an accurate driving voltage DV may be provided to each of the plurality of memories 110 according to the operation timing of each of the plurality of memories 110.

In embodiments of the present disclosure, a driving voltage DV to be supplied to the memory 110 may be adjusted in consideration of the timing of a read or write operation of the memory 110 and the operation status of the memory 110, and thus, it is possible to adaptively adjust the driving voltage DV depending on the timing of a read or write operation and/or the operation status of the memory 110 and improve the operational performance of the memory 110 that operates using the driving voltage DV.

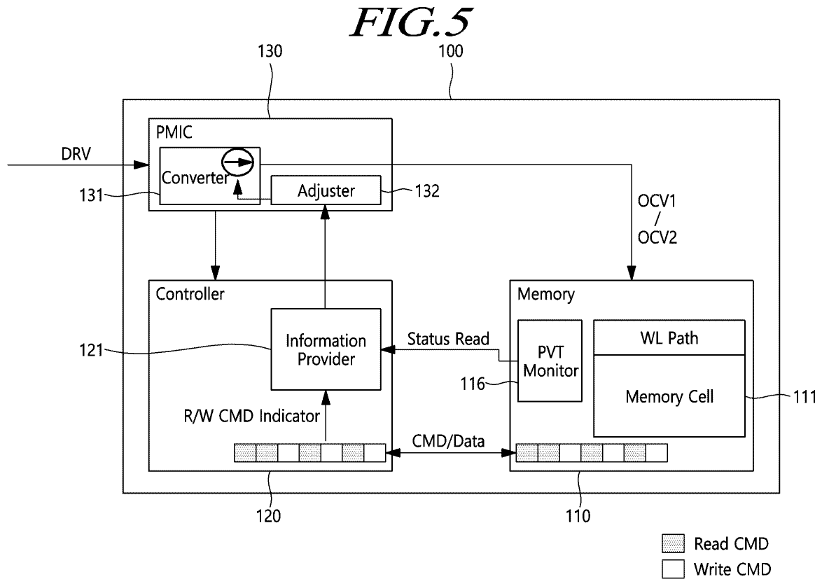

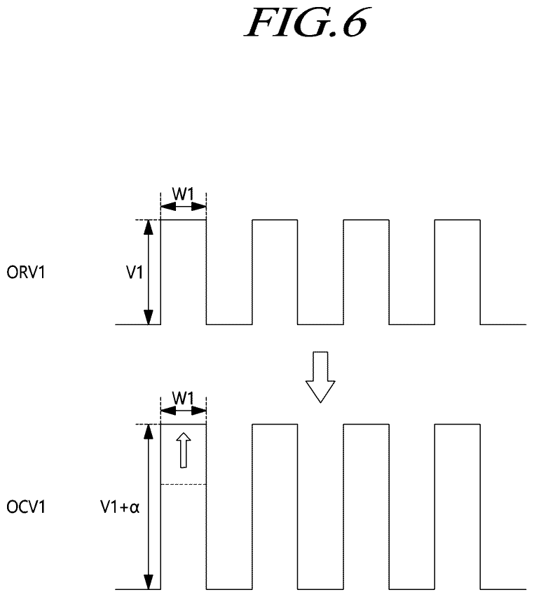

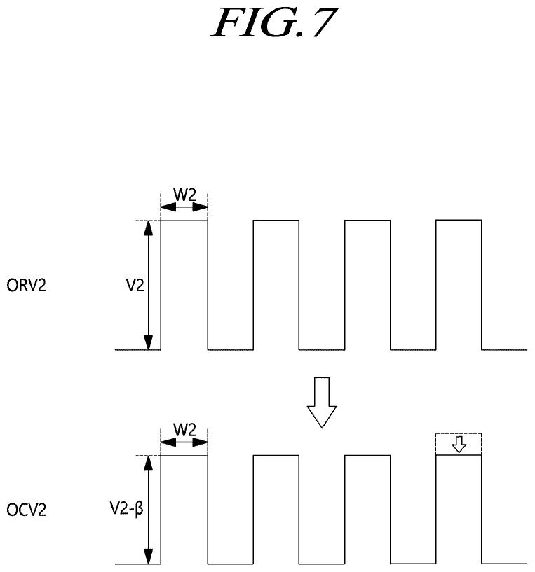

FIG. 5 is a diagram illustrating an example of a configuration for controlling a driving voltage DV in a storage device according to embodiments of the present disclosure. FIGS. 6 and 7 are diagrams illustrating examples in which driving voltages are adjusted by a power management circuit included in a storage device according to embodiments of the present disclosure.

Referring to FIG. 5, a storage device 100 may include a memory 110, a controller 120 and a power management circuit 130.

The memory 110 may include an operation status monitor 116, which monitors the operation status of the memory 110.

The operation status monitor 116 may monitor, for example, the status of the memory 110 regarding process P, voltage V, temperature T, etc. The operation status monitor 116 may monitor information on a status associated with a time during which a voltage applied to a word line WL included in the memory 110 rises to a predetermined level. The operation status monitor 116 may monitor information on process, voltage, temperature, etc. (PVT Monitor) related with the voltage rising time of the word line WL, and may provide the information to the controller 120.

The controller 120 may include an information provider 121, which provides information associated with the operation of the memory 110 to the power management circuit 130.

The information provider 121 may obtain operation timing information according to a command transmitted from the controller 120 to the memory 110.

The information provider 121 may obtain operation status information of the memory 110 from the operation status monitor 116 included in the memory 110. The information provider 121 may receive operation status information from the memory 110 in correspondence to, for example, a status information read command transmitted to the memory 110.

The status information read command may be transmitted, for example, periodically, or may be transmitted to the memory 110 when operation status information is required by the controller 120 to control the memory 110.

The information provider 121 may transmit, to the power management circuit 130, at least one of operation timing information obtained inside the controller 120 and operation status information received from the memory 110.

Operation timing information and operation status information may be provided simultaneously to the power management circuit 130. Alternatively, operation timing information and operation status information may be provided to the power management circuit 130 at different time points. At least one of a time point or a cycle at or with which operation timing information is transmitted to the power management circuit 130 may be different from at least one of a time point or a cycle at or with which operation status information is transmitted to the power management circuit 130.

The power management circuit 130 may include a voltage output 131 and a voltage adjuster 132.

The voltage adjuster 132 may output, to the voltage output 131, a voltage adjustment control signal based on at least one of operation timing information and operation status information received from the controller 120.

The voltage output 131 may output a driving voltage DV based on a driving reference voltage DRV and according to the voltage adjustment control signal received from the voltage adjuster 132.

The voltage output 131 may output a first operation correction voltage OCV1 of a first range or a second operation correction voltage OCV2 of a second range which may be adjusted from the driving reference voltage DRV according to the voltage adjustment control signal.

For example, with read operation timing according to operation timing information, the voltage output 131 may output a first operation reference voltage ORV1 as the first operation correction voltage OCV1. The voltage output 131 may output the first operation correction voltage OCV1, which is adjusted from the first operation reference voltage ORV1 according to operation status information.

For example, referring to FIG. 6, in a read operation of the memory 110, the voltage output 131 may output, to the memory 110, the first operation reference voltage ORV1, which has a voltage level of V1 and a pulse width of W1.

When, according to operation status information of the memory 110 obtained through the controller 120, it is an environment or a state in which the rising time of a voltage applied to a word line WL in the memory 110 is long or the operation speed of the memory 110 is slow, the voltage output 131 may output, to the memory 110, the first operation correction voltage OCV1, which is obtained by raising the level of the first operation reference voltage ORV1 by a.

The amplitude of the first operation correction voltage OCV1 may be different from the amplitude of the first operation reference voltage ORV1. The pulse width or the number of pulses per unit time of the first operation correction voltage OCV1 may be the same as the pulse width or the number of pulses per unit time of the first operation reference voltage ORV1.

Since the first operation correction voltage OCV1, which is obtained by raising the voltage level of the first operation reference voltage ORV1 according to the operation status information, is supplied to the memory 110, the operation speed of the memory 110 may increase. With the pulse width and the number of pulses of the first operation correction voltage OCV1 maintained at the same levels, the operational performance of the memory 110 may be improved while constantly maintaining the operation speed of the memory 110 in an environment or a state in which the operation speed of the memory 110 may decrease.

In another example, at write operation timing according to operation timing information, the voltage output 131 may output a second operation reference voltage ORV2 as the second operation correction voltage OCV2. The voltage output 131 may output the second operation correction voltage OCV2, which is adjusted from the second operation reference voltage ORV2 according to operation status information.

For example, referring to FIG. 7, in a write operation of the memory 110, the voltage output 131 may output, to the memory 110, the second operation reference voltage ORV2, which has a voltage level of V2 and a pulse width of W2. The voltage level V2 may be higher than the voltage level V1 of FIG. 6. The pulse width W2 may be the same as the pulse width W1 of FIG. 6, but embodiments not limited thereto.

When, according to operation status information of the memory 110 obtained through the controller 120, the device is an environment or a state in which the rising time of a voltage applied to a word line WL in the memory 110 is short or the operation speed of the memory 110 is fast, the voltage output 131 may output, to the memory 110, the second operation correction voltage OCV2, which is obtained by lowering the level of the second operation reference voltage ORV2 by β.

The amplitude of the second operation correction voltage OCV2 may be different from the amplitude of the second operation reference voltage ORV2. The pulse width or the number of pulses per unit time of the second operation correction voltage OCV2 may be the same as the pulse width or the number of pulses per unit time of the second operation reference voltage ORV2.

Since the second operation correction voltage OCV2, which is obtained by lowering the voltage level of the second operation reference voltage ORV2 according to the operation status information, is supplied to the memory 110, the operation speed of the memory 110 may decrease. Since the pulse width and the number of pulses of the second operation correction voltage OCV2 are maintained to be the same, the operational performance of the memory 110 may be improved while constantly maintaining the operation speed of the memory 110 in the environment or the state in which the operation speed of the memory 110 may increase.

In this way, according to embodiments of the present disclosure, the power management circuit 130 may provide different driving voltage DV according to a read operation or a write operation of the memory 110 with accurate timing on the basis of operation timing information received from the controller 120.

In addition, since the power management circuit 130 adjusts and outputs the driving voltage DV in a read operation or the driving voltage DV in a write operation on the basis of operation status information of the memory 110 obtained through the controller 120, a driving voltage DV adaptively adjusted depending on the operation status of the memory 110 may be provided to the memory 110.

Voltage supply efficiency may be maintained as the power management circuit 130 provides the driving voltage DV of the memory 110 on the basis of the driving reference voltage DRV input from the outside, and effective control of the driving voltage DV based on operation timing information and operation status information received from the controller 120 may be performed.

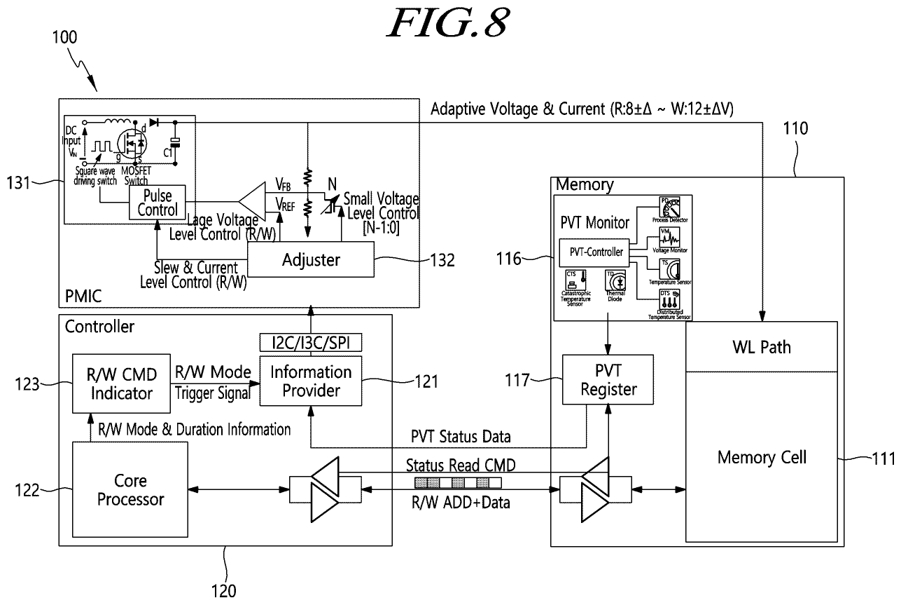

FIG. 8 is a diagram illustrating an example of a configuration for controlling a driving voltage in a storage device according to embodiments of the present disclosure.

Referring to FIG. 8, partial configurations of a memory 110, a controller 120 and a power management circuit 130 included in a storage device 100 are illustrated as an example.

The memory 110 may include, in addition to components such as a memory cell array 111 and peripheral circuits for driving the memory cell array 111, an operation status monitor PVT Monitor 116 and an operation status register PVT Register 117.

The operation status monitor 116 may include, for example, a process detector, a voltage monitor, a temperature sensor, and so on. The operation status monitor 116 may identify a status by comparing an output value that is according to an input value with a reference value using the process detector, or may generate and output monitoring information based on a sensing value obtained through a sensor, etc.

Operation status information outputted by the operation status monitor 116 may be stored in the operation status register 117.

The controller 120 may include an information provider 121, a core processor 122 and a command indicator R/W CMD Indicator 123. The core processor 122 may mean a processor that is included in the aforementioned control circuit.

The core processor 122 may generate a read or write command to control the operation of the memory 110 and data to be transmitted to the memory 110, and may transmit the command and the data to the memory 110.

According to the read or write command from the core processor 122, information on the operation mode and the operation period of the memory 110 may be provided to the command indicator 123.

The command indicator 123 may generate operation timing information on the basis of the information received from the core processor 122, and may output the operation timing information to the information provider 121.

The information provider 121 may transmit the operation timing information received from the command indicator 123 to the power management circuit 130. The information provider 121 may obtain operation status information from the operation status register 117 included in the memory 110.

The operation status information may be received in correspondence to a status information read command transmitted to the memory 110 by the core processor 122. The status information read command may be transmitted to the memory 110 through a channel through which a read command or a write command is transmitted by the core processor 122.

The operation status information may be obtained in accordance with a time point or a cycle at or with which operation timing information is provided to the information provider 121, or may be obtained in accordance with a time point or a cycle different from the time point or the cycle at or with which operation timing information is provided.

The core processor 122 may transmit the status information read command to the memory 110 to provide operation timing information and operation status information together to the power management circuit 130. Alternatively, the core processor 122 may transmit the status information read command to the memory 110 at a time point or with a cycle that requires operation status information to control the operation of the memory 110.

Under the control of the core processor 122, the information provider 121 may provide the operation timing information and the operation status information simultaneously to the power management circuit 130 or may provide the operation timing information and the operation status information to the power management circuit 130 at different time points.

The information provider 121 may transmit the operation timing information and the operation status information to the power management circuit 130 through any one of communication interfaces such as I2C, I3C and SPI, but a communication interface by the information provider 121 is not limited to these examples.

In the power management circuit PMIC 130, a voltage adjuster 132 may receive the operation timing information and the operation status information transmitted by the controller 120. The voltage adjuster 132 may adjust a voltage to be outputted by a voltage output 131, on the basis of the operation timing information and the operation status information.

For example, the voltage adjuster 132 may adjust the level of a voltage Vref, which serves as a reference for voltage generation, and may greatly adjust the level of a voltage to be outputted by the voltage output 131. The voltage adjuster 132 may finely adjust the level of a voltage to be outputted by the voltage output 131 by turning on or off switches (transistors) that connect a plurality of resistors connected to an input terminal of a voltage Vfb used when generating a voltage.

In addition, the voltage adjuster 132 may control the slew rate of a pulse-shaped voltage to be outputted by the voltage output 131 or the value of output current, thereby adjusting the level of a voltage to be outputted by the voltage output 131 or a total amount of current to be supplied by the corresponding voltage.

A scheme in which a voltage to be outputted by the voltage output 131 is adjusted by the voltage adjuster 132 is not limited to the above-described example, and a scheme in which the output of the voltage output 131 is adjusted so that the operational performance of the memory 110 may be constantly maintained according to operation timing information and operation status information of the memory 110 may be included in embodiments of the present disclosure.

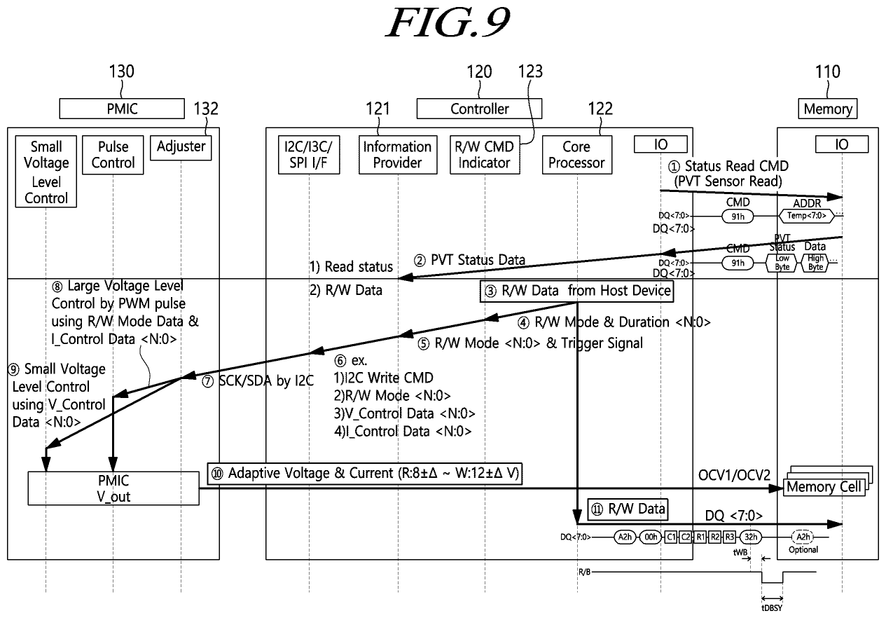

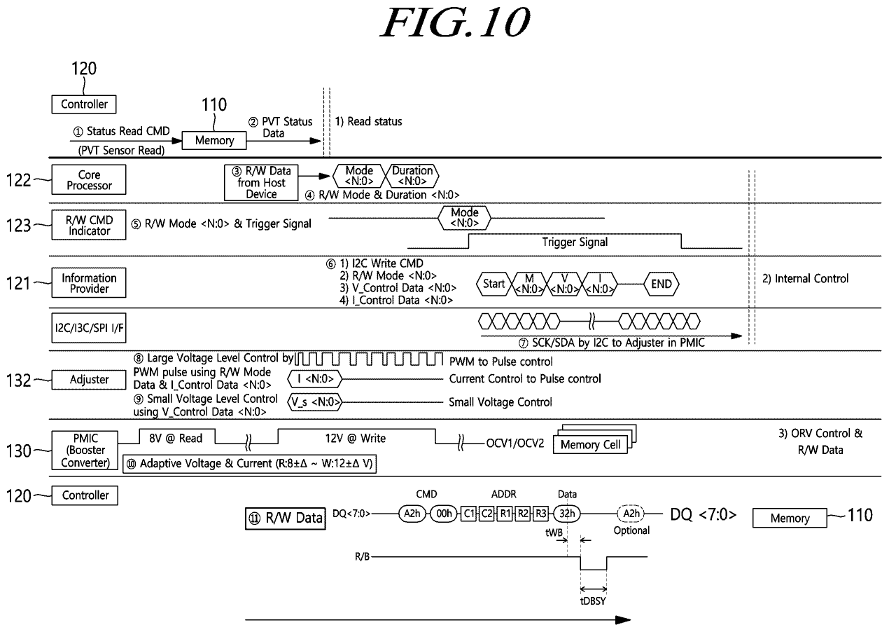

FIGS. 9 and 10 are diagrams illustrating an example of a scheme in which driving voltage control is performed in a storage device illustrated in FIG. 8.

FIG. 9 illustrates, in terms of respective components, timing at which signals, commands, etc. for driving voltage control are transmitted and received between the memory 110, the controller 120 and the power management circuit 130 of the storage device 100, and FIG. 10 illustrates a temporal order in which the signals, the commands, etc. are transmitted and received.

Referring to FIGS. 9 and 10, in order to obtain the operation status information of the memory 110, the controller 120 may transmit a status information read command to the memory 110 (\textcircled{1}). In correspondence to the status information read command, the controller 120 may receive operation status information from the memory 110 (\textcircled{2}). The status information read command and the operation status information may be transmitted and received through the input and output terminals of the controller 120 and the memory 110. The operation status information read from the memory 110 may be managed by being transferred to the information provider 121 of the controller 120.

In a state in which the operation status information of the memory 110 is managed by the information provider 121 of the controller 120, a read command or a write command may be generated by a host device 200 (\textcircled{3}).

The core processor 122 may provide information on the operation mode and the operation period of the memory 110 according to the read command or the write command, etc. to the command indicator 123 (\textcircled{4}).

The command indicator 123 may provide the information on the operation mode, etc. received from the core processor 122, to the information provider 121 (\textcircled{5}). The command indicator 123 may provide operation timing information generated on the basis of the information received from the core processor 122, to the information provider 121. The command indicator 123 may also provide a signal that triggers operating voltage control according to the information on the operation mode, the operation timing information, etc., to the information provider 121.

The information provider 121 may generate a signal for controlling an operating voltage according to the information or the trigger signal received from the command indicator 123, and may transmit the signal to the power management circuit 130 (©). The information provider 121 may transmit a signal, information or a command to the power management circuit 130 through a communication interface such as I2C, I3C and SPI. For example, the information provider 121 may transmit a serial clock SCK and serial data SDA to the power management circuit 130 by I2C (\textcircled{7}).

The signal or the command transmitted to the power management circuit 130 by the information provider 121 may be, for example, a write command according to I2C or the operation timing information described above. Alternatively, data for adjusting a voltage or data for adjusting a current to adjust an operating voltage may be transmitted to the power management circuit 130 by the information provider 121. The type of information transmitted from the information provider 121 to the power management circuit 130 is not limited thereto, and various types of information that may instruct the adjustment of an operating voltage by the power management circuit 130 may be transmitted to the power management circuit 130.

The voltage adjuster 132 of the power management circuit 130 may adjust a driving reference voltage DRV, which is an operating voltage, on the basis of the signal or the command received from the information provider 121.

For example, the voltage adjuster 132 may perform large voltage level adjustment by using a pulse width modulation signal using the operation timing information received from the information provider 121 and current control data (\textcircled{8}). The pulse width modulation signal may be a signal that adjusts the width of a pulse to be inputted to the voltage output 131. The current control data may be data that instructs current control for pulse adjustment.

In another example, the voltage adjuster 132 may perform small voltage level adjustment by using voltage control data received from the information provider 121 (\textcircled{9}). The voltage control data may be data that instructs voltage control for pulse adjustment.

The power management circuit 130 may adjust the level of an operating voltage in a large range or a small range using the voltage adjuster 132, and may output a first operation correction voltage OCV1 or a second operation correction voltage OCV2 as an adjusted operating voltage to the memory 110 (\textcircled{10}).

The core processor 122 of the controller 120 may transmit a read command or a write command to the memory 110 in accordance with timing at which the adjusted operating voltage is supplied to the memory 110 (\textcircled{11}). The read command or the write command may be inputted to the memory 110, for example, after the level of an operating voltage supplied to the memory 110 is changed. The memory 110 may perform an operation according to the read command or the write command by using the first operation correction voltage OCV1 or the second operation correction voltage OCV2 as an adjusted operating voltage.

Since operation control according to a read command or a write command is performed using an operating voltage whose voltage level is adjusted based on the operation status information of the memory 110, power consumption may be reduced or the operational performance of the memory 110 may be improved, whereby optimized operation control may be performed.

Although various embodiments of the present disclosure have been described with particular specifics and varying details for illustrative purposes, those skilled in the art will appreciate that various modifications, additions and substitutions may be made based on what is disclosed or illustrated in the present disclosure without departing from the spirit and scope of the present disclosure as defined in the following claims.

What is claimed is:

1. A storage device comprising:
at least one memory;
a controller configured to control an operation of the at least one memory; and
a power management circuit configured to receive a driving reference voltage from an outside, receive operation timing information according to a command transmitted from the controller to the at least one memory, and output, to the at least one memory, a first operation correction voltage of a first range or a second operation correction voltage of a second range that is adjusted from the driving reference voltage on the basis of the operation timing information.

2. The storage device according to claim 1, wherein the power management circuit receives, from the controller, operation status information obtained in the at least one memory, and on the basis of the operation status information, adjusts a first operation reference voltage different from the driving reference voltage to the first operation correction voltage or adjusts a second operation reference voltage corresponding to the driving reference voltage to the second operation correction voltage.

3. The storage device according to claim 2, wherein an amplitude of each of the first operation reference voltage and the second operation reference voltage is different from the amplitude of each of the first operation correction voltage and the second operation correction voltage, and a pulse width of each of the first operation reference voltage and the second operation reference voltage is the same as the pulse width of each of the first operation correction voltage and the second operation correction voltage.

4. The storage device according to claim 3, wherein a number of pulses per unit time of each of the first operation reference voltage and the second operation reference voltage is the same as a number of pulses per unit time of each of the first operation correction voltage and the second operation correction voltage.

5. The storage device according to claim 2, wherein at least one of a time point or a cycle at or with which the power management circuit receives the operation status information is different from at least one of a time point or a cycle at or with which the power management circuit receives the operation timing information.

6. The storage device according to claim 2, wherein the first range is a range that is set on the basis of the first operation reference voltage, and the second range is a range that is set on the basis of the second operation reference voltage.

7. The storage device according to claim 1, wherein the driving reference voltage is included in the second range.

8. The storage device according to claim 1, wherein the first range does not overlap the second range.

9. The storage device according to claim 1, wherein the first operation correction voltage or the second operation correction voltage is applied to at least one word line included in the at least one memory.

10. The storage device according to claim 1, wherein the power management circuit comprises:
a first output configured to output the first operation correction voltage;
a second output configured to output the second operation correction voltage; and
a switching unit configured to electrically connect the first output and the second output with the at least one memory.

11. The storage device according to claim 10, wherein the switching unit electrically connects at least one first memory, which performs a read operation among the at least one memory, and the first output, and electrically connects at least one second memory, which performs a write operation among the at least one memory, and the second output.

12. The storage device according to claim 10, wherein the switching unit is electrically connected to each of the at least one memory through a single port that is included in each of the at least one memory.

13. The storage device according to claim 10, wherein the switching unit operates according to the operation timing information or a control signal based on the operation timing information.

14. A power management circuit comprising:
a voltage adjuster configured to output a voltage adjustment control signal based on at least one of operation timing information or operation status information received from a controller; and
a voltage output configured to receive a driving reference voltage from an outside, and output at least one operation correction voltage that is obtained as the driving reference voltage adjusted according to the voltage adjustment control signal.

15. The power management circuit according to claim 14, wherein the voltage output outputs a first operation correction voltage that is adjusted from a first operation reference voltage different from the driving reference voltage at read operation timing according to the operation timing information.

16. The power management circuit according to claim 15, wherein the voltage output outputs a second operation correction voltage that is adjusted from a second operation reference voltage corresponding to the driving reference voltage at write operation timing according to the operation timing information.

17. The power management circuit according to claim 16, wherein the voltage output comprises:
a first output configured to output the first operation correction voltage;
a second output configured to output the second operation correction voltage; and
a switching unit configured to electrically connect the first output and the second output with a plurality of output terminals.

18. The power management circuit according to claim 17, wherein each of the plurality of output terminals is electrically connected in correspondence to each of a plurality of memories.

19. A power management circuit comprising:
a first output configured to output a first operation reference voltage that which is different from a driving reference voltage received from an outside;
a second output configured to output a second operation reference voltage that which corresponds to the driving reference voltage; and
a switching unit including a plurality of switches, each of which electrically connects each of a plurality of output terminals and the first output or the second output, wherein at least two switches among the plurality of switches are electrically connected simultaneously to the first output or the second output.

20. A storage device comprising:
at least one memory;
a controller configured to control an operation of the at least one memory; and
a power management circuit configured to receive a driving reference voltage from an outside, to receive operation timing information or operation status information from the controller, and to output, to the at least one memory, a driving voltage that is adjusted from the driving reference voltage based on the operation timing information or the operation status information.
